(19) United States
(12) Patent Application Publication
(10) Pub. No.: US 2026/0043843 A1
(43) Pub. Date: Feb. 12, 2026

(54) CONNECTOR FOR USE WITH BURN-IN DEVICE

(71) Applicant: Expert International Mercantile Corporation, Hsinchu (TW)

(72) Inventors: WEI-CHIH SUN, Hsinchu (TW); WEN-HSU CHANG, Hsinchu (TW)

(21) Appl. No.: 18/969,462

(22) Filed: Dec. 5, 2024

(30) Foreign Application Priority Data
Aug. 9, 2024 (TW) 113130050

(51) Int. Cl. G01R 31/28; G01R 1/04

(52) U.S. Cl. CPC G01R 31/2863; G01R 1/0408

(57) ABSTRACT

A connector includes a contact interface. The contact interface includes a surface, multiple metal contacts and at least two bumps. The bumps are formed on the surface. The bumps are of a height not greater than a height by which the multiple metal contacts protrude from the surface, and thus the bumps function as a restraint or a buffer to the contact interface and thus prevent the multiple metal contacts from undergoing excessive deformation when the contact interface is connected to another contact interface.

### RELATED APPLICATIONS

This application claims priority to Taiwan Application Serial Number 113130050, filed on Aug. 9, 2024, which is incorporated by reference herein in its entirety.

### BACKGROUND OF THE INVENTION

### Field of the Invention

The present disclosure relates to connectors, particularly to a connector for use with a burn-in device, and more particularly to a connector designed to reduce required wiring materials and achieve space optimization.

### Description of the Prior Art

Burn-in test devices each comprise a bulky circuit board and multiple test sockets. The test sockets conventionally have operable mechanisms, such as lid-liftable sockets and lid-slidable test sockets. The test sockets may also have retracting mechanisms.

FIG. 1 schematically shows a conventional lid-liftable socket (1000) that has a base (1100) and a lid (1200). The base (1100) and the lid (1200) are pivotally connected, for example, by a pivot (1300). The bottom surface of the base (1100) is fixedly connected to a circuit board (2000). The base (1100) has a receiving space for receiving a device under test (DUT). The receiving space has a plurality of metal contacts for electrically connecting to the DUT to allow the DUT to electrically connect to the base (1100). The lid (1200) has a heat dissipation means (1220) and a heat-conducting element (1230). The heat-conducting element (1230) protrudes from a bottom (1210) of the lid (1200) to come into contact with the top of the DUT, absorb heat from the DUT, and transfer the heat to the heat dissipation means (1220). The heat-conducting element (1230) is, for example, a cooling fin. The lid-liftable socket (1000) comprises a connector. The connector has an upper contact portion (1240) fixed to the lid (1200) and a lower contact portion (2100) fixed to the base (1100). The upper contact portion (1240) has an upper contact interface (1250). The lower contact portion (2100) has a lower contact interface (2200). The upper contact interface (1250) and the lower contact interface (2200) are configured to be able to coordinate with each other and be electrically connected when the base (1100) is operated at a shutdown position. As shown in the diagram, the upper contact interface (1250) has protruding metal contacts, and the lower contact interface (2200) has concave metal contacts corresponding in shape to the protruding metal contacts.

FIG. 2A and FIG. 2B show a test socket that has a retracting mechanism and comprises a base (20), a platform (30), a lid (40) and a casing (50). The base (20) is electrically connected to a circuit board (not shown). The platform (30) is connected to the base (20) through a resilient connection means. The lid (40) is disposed above the platform (30) and configured to selectively press against the platform (30) when manipulated. A plurality of metal contacts are disposed on a bottom of the base (20) and electrically connected to the circuit board. A casing (50) comprises two sidewalls fixed to two sides of the base (20) respectively, confining the platform (30) and the lid (40) to above the base (20). A lower contact portion (21) of a connector is disposed on the other side of the base (20), and the other side of the base (20) can retract relative to the platform (30). The lower contact portion (21) and the base (20) are electrically connected. The platform (30) comprises a pair of rails (31) and a tray (32). The rails (31) are configured to move vertically relative to the base (20). The two sides of the tray (32) are connected to the pair of rails (31) by a sliding means; thus, the tray (32) slides horizontally relative to the rails (31) and between a retracting position and a protruding position, allowing a depression for containing the DUT to be formed on the tray (32). The bottom surface of the depression has a plurality of metal contacts for electrically connecting to the DUT.

FIG. 2C shows the shutdown state of the test socket. The platform (30) is located at the retracting position. An engaging element (44) and a handle (60) are manipulated to cause the lid (40) to press downward against the platform (30), allowing the lid (40) to come into contact with the DUT. FIG. 2D shows the test socket in the shutdown state. An upper contact portion (35) of the connector extends from one end of the platform (30) to coordinate with the lower contact portion (21) and becomes electrically connected thereto as a result of a descent of the platform (30). As shown in the diagram, an upper contact interface of the upper contact portion (35) has multiple protruding metal contacts, and a lower contact interface of the lower contact portion (21) has multiple metal contacts corresponding in position to the multiple protruding metal contacts respectively.

FIG. 3 illustrates another specific variant embodiment of a lower contact portion (200) of the connector. The lower contact portion (200) has a body (214). The body (214) has a front end (215), a pair of installation mechanisms (214A, 214B), an opening array (214C) and another opening array (214D). The front end (215) is configured to function as an insertion end for multiple conducting wires (850, 840). The installation mechanisms (214A, 214B) coordinate with a conventional installation means, such as screws, to fix the body (214) to a circuit board. The opening arrays (214C, 214D) are aligned along two parallel axes (920, 930) on a top (216) respectively, and the opening arrays (214C, 214D) expose multiple protruding metal contacts (231), forming a lower contact interface. The metal contacts (231) are electrically connected to the conducting wires (850, 840) inside the body (214) respectively.

Resilience is exhibited by the metal contacts protruding from the contact interfaces, in the upper contact portion (1240) and the lower contact portion (2100) of FIG. 1, in the upper contact portion (35) and the lower contact portion (21) of FIG. 2D, and in the lower contact portion (200) of FIG. 3. During the operation, the upper contact interface and the lower contact interface collide and thus cause the loss of resilience of the metal contacts or the irretrievable deformation of the metal contacts, leading to poor contact of the electrical connection of the connector to the detriment of the functionality of the test sockets.

### SUMMARY OF THE INVENTION

In view of the aforesaid drawbacks of the prior art, it is an objective of the disclosure to provide a connector comprising a contact interface. The contact interface comprises a surface, multiple metal contacts, and at least two bumps. The multiple metal contacts protrude from the surface. The at least two bumps are formed on the surface. The at least two bumps are of a height not greater than a height by which the multiple metal contacts protrude from the surface. Therefore, the at least two bumps function as a buffer to the contact interface to prevent the multiple metal contacts from undergoing excessive deformation when the contact interface is connected to another contact interface.

In an embodiment, the contact interface further comprises at least one opening array having multiple openings defined on the surface, allowing the multiple metal contacts to protrude from the multiple openings.

In an embodiment, the at least one opening array comprises a first opening array and a second opening array, with the at least two bumps disposed between the first opening array and the second opening array.

In an embodiment, the at least two bumps are disposed between the openings of the at least one opening array.

In an embodiment, the at least two bumps are cylinders.

In an embodiment, the at least two bumps are striplike.

Another objective of the disclosure is to provide a burn-in device, comprising: a circuit board having a lower contact interface for a connector, with the lower contact interface electrically connected to the circuit board; and a test socket comprising a base and a lid, the base being fixed to the circuit board, the lid being movably connected to the base, the lid being operable between a start position and a shutdown position, the lid having an upper contact interface for the connector, with the upper contact interface electrically connected to one or more electronic components of the lid, wherein the upper contact interface is electrically connected to the lower contact interface when the lid is operated at the shutdown position. The lower contact interface or the upper contact interface comprises the surface, the multiple metal contacts and the at least two bumps.

Yet another objective of the disclosure is to provide a test socket, comprising: a base having a lower contact interface for a connector; and a lid movably connected to the base, being operable between a start position and a shutdown position, and having an upper contact interface for the connector, with the upper contact interface electrically connected to one or more electronic components of the lid, wherein the upper contact interface is electrically connected to the lower contact interface when the lid is operated at the shutdown position. The lower contact interface or the upper contact interface comprises the surface, the multiple metal contacts and the at least two bumps.

The aforesaid aspects and other aspects of the disclosure are illustrated by non-restrictive, specific embodiments, depicted by accompanying drawings, described below and thus rendered clearer.

### BRIEF DESCRIPTION OF THE DRAWINGS

The disclosure is depicted by drawings, illustrated by non-restrictive, non-exhaustive embodiments, and described below. The drawings are not drawn to scale but are aimed at disclosing the structural features and principles of the disclosure.

FIG. 1 (PRIOR ART) schematically shows a lid-liftable test socket and its wireless connector.

FIG. 2A through FIG. 2D (PRIOR ART) show a test socket with a retracting mechanism and its wireless connector.

FIG. 3 (PRIOR ART) shows a contact interface for a connector.

FIG. 4A through FIG. 4F show a connector according to an embodiment of the disclosure.

FIG. 5A through FIG. 5C show a contact interface for the connector according to a variant embodiment of the disclosure.

FIG. 6 shows the connector according to another embodiment of the disclosure.

FIG. 7 shows the connector according to yet another embodiment of the disclosure.

FIG. 8 shows the connector according to still yet another embodiment of the disclosure.

FIG. 9 shows the connector according to a further embodiment of the disclosure.

### DETAILED DESCRIPTION OF THE EMBODIMENTS

The disclosure is described in detail below with reference made to the drawings and specific embodiment of specific examples. However, the subject matters claimed by the disclosure can be specifically implemented in many different ways; thus, the construction of the claims of the disclosure or the scope thereof is not restricted to the specific embodiments of any examples disclosed herein. The specific embodiments of the specific examples serve illustrative purposes only. Likewise, the disclosure is aimed at defining reasonably broad scope of the subject matter falling within the scope of or claimed by the disclosure.

The expression “in an embodiment” used herein does not necessarily refer to the same specific embodiment. Furthermore, the expression “in other (a few/some) embodiments” used herein does not necessarily refer to different specific embodiments. The expressions are aimed at, for example, enabling the claimed subject matter to include the combination of all or part of exemplary, specific embodiments.

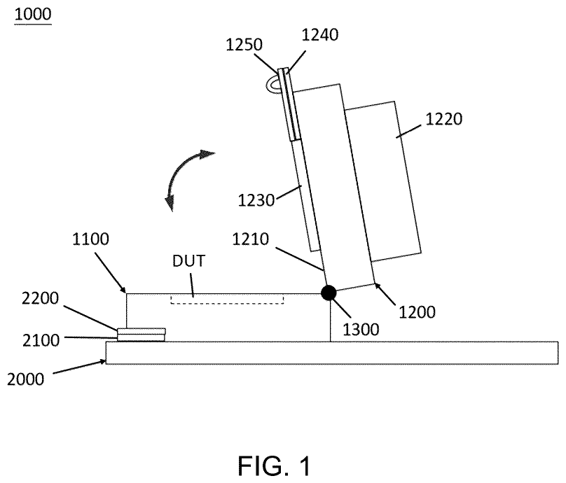

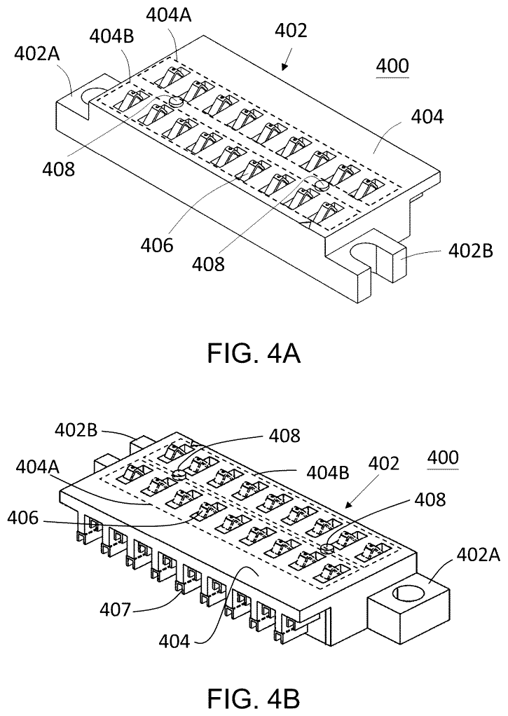

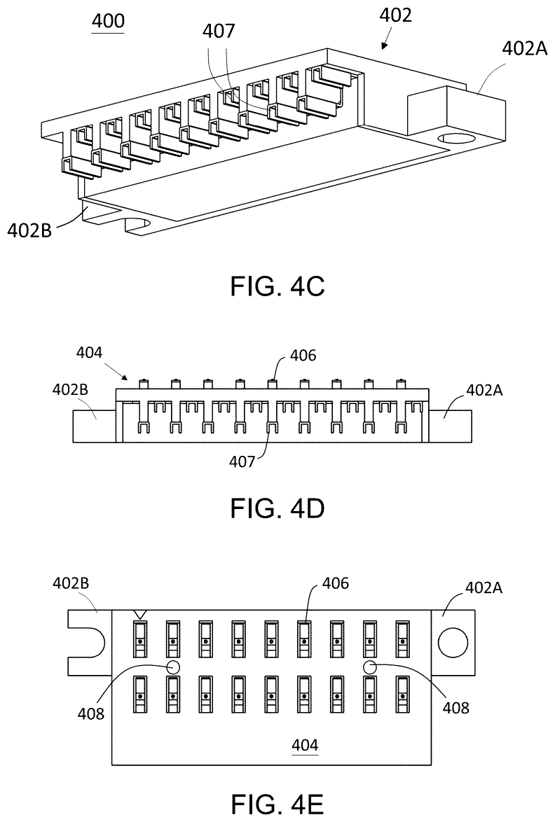

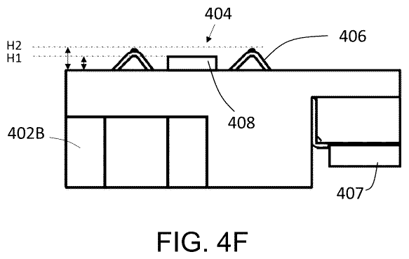

FIG. 4A through FIG. 4F depict an embodiment of the disclosure. A connector (400) can substitute for the lower contact portion (2100) and its lower contact interface (2200) shown in FIG. 1. The connector (400) comprises a body (402). The body (402) is configured to provide a contact interface (404). The contact interface (404) can be the lower contact interface (2200) shown in FIG. 1. The contact interface (404) has a surface, and at least one opening array is defined on the surface. FIG. 4A and FIG. 4B show that the contact interface (404) has a first opening array (404A) and a second array (404B). The first opening array (404A) has nine openings, and the second array (404B) has nine openings, with the first opening array (404A) and the second array (404B) being aligned and parallel. In another embodiment, the first opening array (404A) and the second array (404B) are not aligned. The contact interface (404) further has multiple metal contacts (406) protruding from the openings. The metal contacts (406) have resilience and thus can deform and descend toward the inside of the openings when pressed. As shown in FIG. 4B and FIG. 4C, the body (402) has a front end configured to provide multiple metal contacts (407) for connecting to the conducting wires. The metal contacts (406) are electrically connected to the metal contacts (407) respectively. The metal contacts (407) are structurally configured to be able to connect to free ends of the conducting wires respectively, allowing the free ends of the conducting wires to be easily welded to the metal contacts (407). The conducting wires are conducting wires electrically connected to a circuit board. Therefore, the connector (404) is electrically connected to the circuit board, but the disclosure is not limited thereto.

FIG. 4A, FIG. 4B and FIG. 4E show that at least two bumps (408) are formed on the surface of the contact interface (404). The bumps (408) are cylinders and are disposed between the first opening array (404A) and the second array (404B), but the disclosure is not limited thereto. FIG. 4F shows that the bumps (408) protrude from the surface of the contact interface (404) by a height (H1) less than a height (H2) by which the metal contacts (406) protrude from the surface. The bumps (408) are conducive to the reduction of mechanical impacts on the metal contacts (406), for example, in the situation when the upper contact interface (1250) and the lower contact interface (2200) are connected as shown in FIG. 1. Specifically speaking, the bumps (408) prevent the metal contacts (406) from being excessively compressed and thus irretrievably deformed to the detriment of the signal transmission performance of the connector (400).

A pair of installation mechanisms (402A, 402B) are disposed on the two sides of the body (402) respectively and configured to allow the application of a conventional fixing means (for example, screws) to fix the body (402) to a circuit board to form the lower contact portion (2100) and the lower contact interface (2200) as shown in FIG. 1, but the disclosure is not limited thereto.

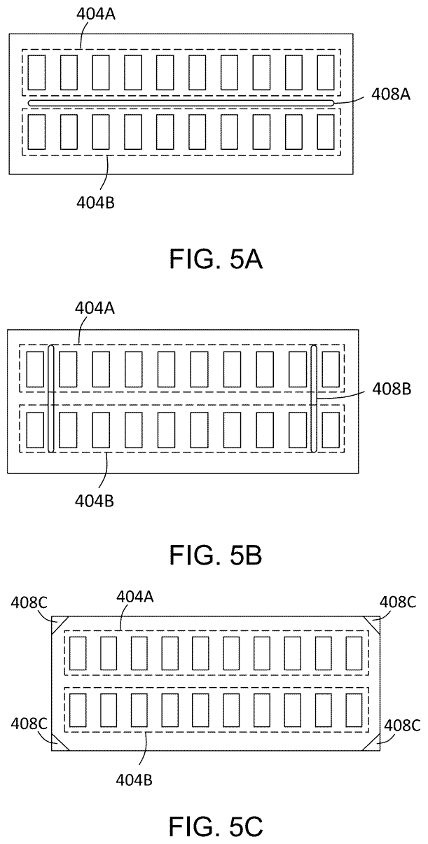

FIG. 5A through FIG. 5C show a contact interface for the connector according to a variant embodiment of the disclosure. FIG. 5A shows a bump (408A) that is striplike and extends between the first opening array (404A) and the second array (404B). FIG. 5B shows two bumps (408B), each of which is striplike and has two ends extending to reach the first opening array (404A) and the second array (404B) respectively. FIG. 5C shows four bumps (408C) disposed at the corners of the contact interface respectively, surrounding the first opening array (404A) and the second array (404B).

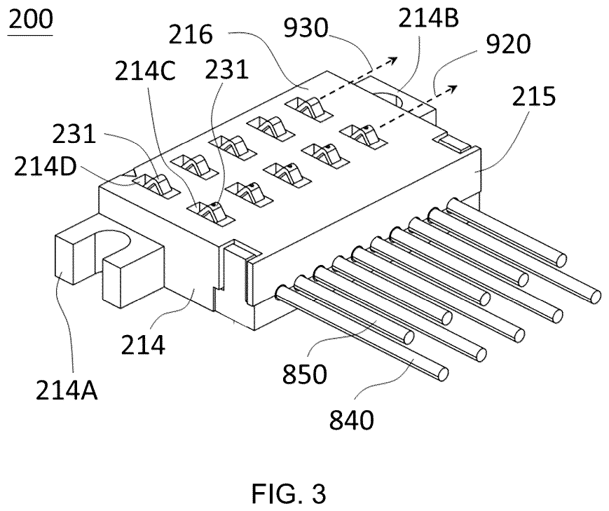

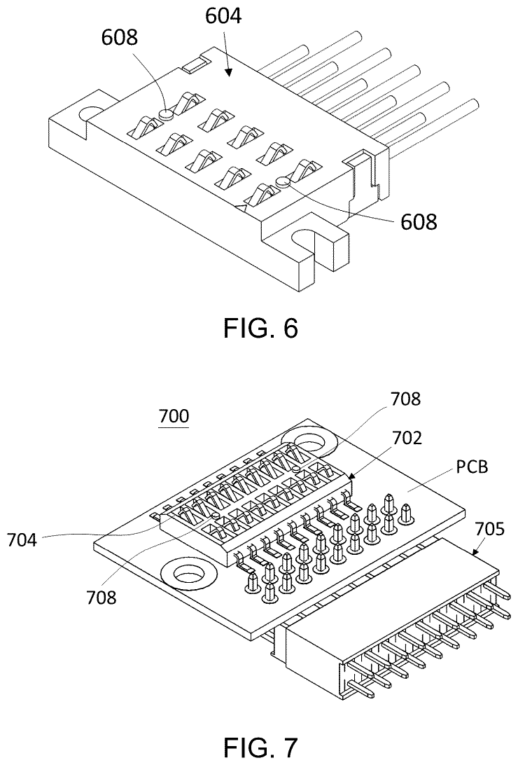

FIG. 6 shows the connector according to another embodiment of the disclosure, which is like the connector (200) of FIG. 3. Two bumps (608) are formed on the surface of a contact interface (604).

FIG. 7 shows the connector according to yet another embodiment of the disclosure, which can be regarded as a variant of the connector (200) of FIG. 3 and the connector (400) of FIG. 4. The connector (700) has a first body (702) fixed to a circuit board (PCB). A surface of the first body (702) provides a contact interface (704). The first body (702) has multiple terminals fixed to a circuit board (PCB) by welding. Then, the circuit board (PCB) is electrically connected to a second body (705) through the multiple bent terminals. The second body (705) is further connected to another circuit board or a corresponding connector structure. Two bumps (708) are formed on the contact interface (704) in the same manner as depicted in FIG. 4E.

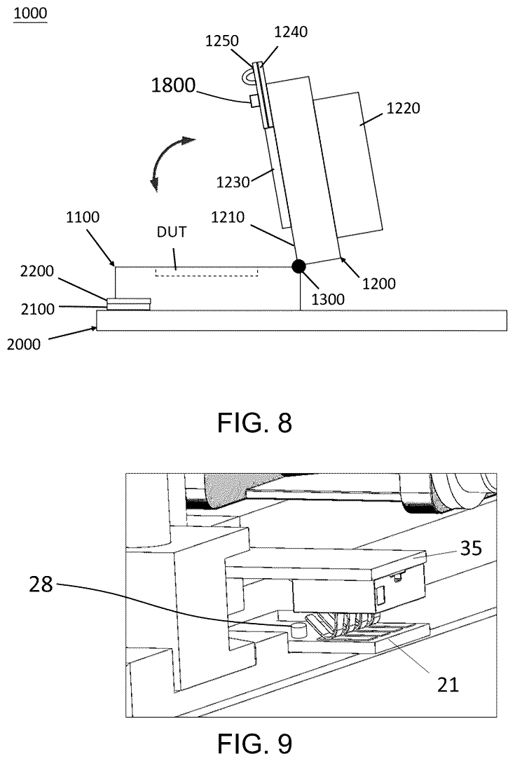

FIG. 8 shows the connector according to still yet another embodiment of the disclosure. FIG. 8 is distinguished from FIG. 1 in that at least one bump (1800) of FIG. 8 is formed on the upper contact interface (1250) of the lid-liftable socket (1000) of FIG. 1. Therefore, when the upper contact interface (1250) is connected to the lower contact interface (2200), the bump (1800) functions as a restraint or a buffer to prevent the protruding metal contacts of the upper contact interface (1250) from being excessively compressed and thus irretrievably deformed.

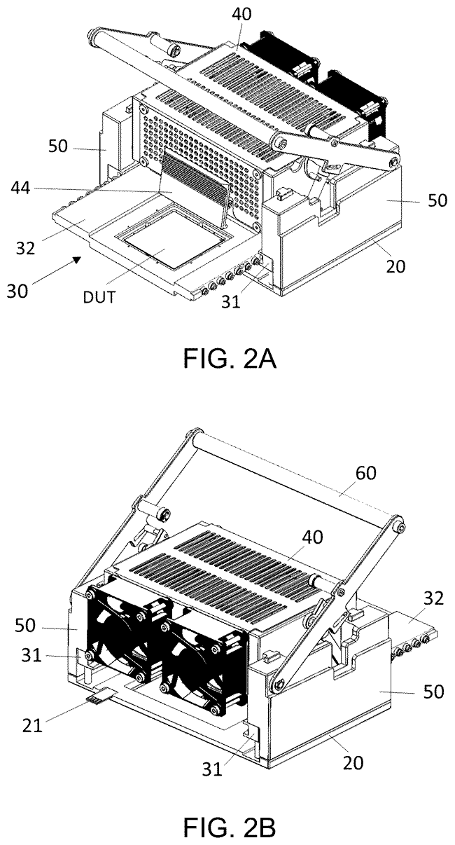

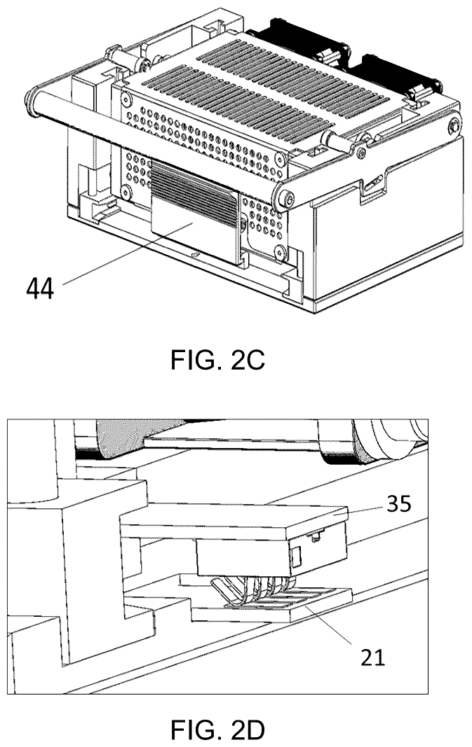

FIG. 9 shows the connector according to a further embodiment of the disclosure. FIG. 9 is distinguished from FIG. 2D in that at least one bump (28) of FIG. 9 is formed on the surface of the lower contact portion (21) of the test socket connector of FIG. 2D, and multiple metal contact pads are disposed on the contact interface of the lower contact portion on which the bump (28) is disposed. When the multiple protruding resilient metal contacts of the upper contact portion (35) descend until the multiple protruding resilient metal contacts come into contact with the metal contact pads of the lower contact portion (21), the bump (28) functions as a restraint or a buffer to prevent the upper contact portion (35) from excessively descending, preventing the metal contacts of the upper contact portion (35) from being excessively compressed.

Therefore, a connector of the disclosure is described above and illustrated by drawings. The embodiments (or technical solutions/features) of the disclosure are not necessarily for sole use or application. Persons skilled in the art may integrate or partially integrate at least any two of the embodiments (or technical solutions/features) into the same embodiment as needed. Specific embodiments of the disclosure merely serve illustrative purposes. All changes can be made to the disclosure without departing from the spirit and scope of the claims of the disclosure and still fall within the scope of the claims of the disclosure. Therefore, specific embodiments described herein are not restrictive of the disclosure, whereas the true scope and spirit of the disclosure shall be defined by the appended claims.

What is claimed is:

1. A connector, comprising:
a contact interface, comprising:
a surface;
multiple metal contacts protruding from the surface; and
at least two bumps formed on the surface and being of a height not greater than a height by which the multiple metal contacts protrude from the surface to allow the at least two bumps to function as a buffer to the contact interface and thus prevent the multiple metal contacts from undergoing excessive deformation when the contact interface is connected to another contact interface.

2. The connector of claim 1, wherein the contact interface further comprises at least one opening array having multiple openings defined on the surface, allowing the multiple metal contacts to protrude from the multiple openings.

3. The connector of claim 2, wherein the at least one opening array comprises a first opening array and a second opening array, with the at least two bumps disposed between the first opening array and the second opening array.

4. The connector of claim 2, wherein the at least two bumps are disposed between the openings of the at least one opening array.

5. The connector of claim 2, wherein the at least two bumps are cylinders.

6. The connector of claim 2, wherein the at least two bumps are striplike.

7. A burn-in device, comprising:
a circuit board having a lower contact interface for a connector, with the lower contact interface electrically connected to the circuit board; and
a test socket comprising a base and a lid, the base being fixed to the circuit board, the lid being movably connected to the base, the lid being operable between a start position and a shutdown position, the lid having an upper contact interface for the connector, with the upper contact interface electrically connected to one or more electronic components of the lid, wherein the upper contact interface is electrically connected to the lower contact interface when the lid is operated at the shutdown position,
wherein the lower contact interface or the upper contact interface comprises:
a surface;
multiple metal contacts protruding from the surface; and
at least two bumps formed on the surface and being of a height not greater than a height by which the multiple metal contacts protrude from the surface to allow the at least two bumps to function as a buffer to the lower contact interface or the upper contact interface and thus prevent the multiple metal contacts from undergoing excessive deformation when the upper contact interface is connected to the lower contact interface.

8. A test socket, comprising:
a base having a lower contact interface for a connector; and
a lid movably connected to the base, being operable between a start position and a shutdown position, and having an upper contact interface for the connector, with the upper contact interface electrically connected to one or more electronic components of the lid, wherein the upper contact interface is electrically connected to the lower contact interface when the lid is operated at the shutdown position,
wherein the lower contact interface or the upper contact interface comprises:
a surface;
multiple metal contacts protruding from the surface; and
at least two bumps formed on the surface and being of a height not greater than a height by which the multiple metal contacts protrude from the surface to allow the at least two bumps to function as a buffer to the lower contact interface or the upper contact interface and thus prevent the multiple metal contacts from undergoing excessive deformation when the upper contact interface is connected to the lower contact interface.
